(19) United States
(12) Patent Application Publication
(10) Pub. No.: US 2014/0345685 A1
(43) Pub. Date: Nov. 27, 2014

(54) Photovoltaic Cell And Method Of Forming The Same

(71) Applicant: Dow Corning Corporation, Midland, MI (US)

(72) Inventors: John D. Albaugh, Freeland, MI (US); Guy Damien Serge Beaucarne, Oud-heverlee (BE); Nicholas E. Powell, Midland, MI (US); Adriana Petkova Zambova, Midland, MI (US)

(21) Appl. No.: 14/364,794

(22) PCT Filed: Dec. 13, 2012
(86) PCT No.: PCT/US12/69465

§ 371 Date: Jun. 12, 2014

Related U.S. Application Data
(60) Provisional application No. 61/569,977, filed on Dec. 13, 2011.

(51) Int. Cl. H01L 31/0224

(52) U.S. Cl. CPC H01L 31/022458
USPC 136/256; 438/98

(57) ABSTRACT

A photovoltaic cell comprises a base substrate comprising silicon and including a rear region. A first electrode is disposed on, and is in electrical communication with, the rear region, and comprises a first metal present in the first electrode in a majority amount. A second electrode is spaced from the rear region such that the rear region is free of physical contact with the second electrode. The second electrode is in electrical contact with the first electrode. The second electrode comprises a polymer, a second metal present in the second electrode in a majority amount, and a third metal different from the first and second metals. The third metal has a melting temperature of no greater than about 300° C. The rear region is in electrical communication with the second electrode via the first electrode. A method of forming the PV cell is also provided.

### CROSS REFERENCE TO RELATED APPLICATIONS

This application claims the benefit of U.S. Provisional Patent Application Ser. No. 61/569,977, filed on Dec. 13, 2011, which is incorporated herewith by reference in its entirety.

### FIELD OF THE INVENTION

The present invention generally relates to a photovoltaic (PV) cell and to a method of forming the PV cell.

### BACKGROUND

Rear surface metallization is an important aspect of photovoltaic (PV) cells which allows for transport and transport of charge carriers. The metallization is generally in the form of an electrode (e.g. a layer of aluminum), which typically includes contacts formed from silver (Ag). The contacts are disposed through the rear layer. The contacts can be in the form of busbars or pads. Tabbing, e.g. ribbon, is soldered to the contacts to connect multiple PV cells together (e.g. in series). Typically, the contacts are formed using pastes which include Ag as a primary component due to its excellent conductivity. Unfortunately, such metallization makes up a substantial portion of overall manufacturing cost due to reliance on Ag being present in the contacts as well as in other components of the PV cells, e.g. fingers. As such, there remains an opportunity to provide improved PV cells and methods of forming the same.

### SUMMARY OF THE INVENTION

The present invention provides a photovoltaic (PV) cell. The PV cell comprises a base substrate comprising silicon and includes a rear region. A first electrode is disposed on the rear region of the base substrate and has an outer surface. The first electrode is in electrical contact with the rear region of the base substrate. The first electrode comprises a first metal present in the first electrode in a majority amount. A second electrode is spaced from the rear region of the base substrate such that the rear region of the base substrate is free of physical contact with the second electrode. The second electrode is in electrical contact with the first electrode. The second electrode comprises a polymer. The second electrode further comprises a second metal present in the second electrode in a majority amount. The second electrode further comprises a third metal different from the first metal of the first electrode and the second metal of the second electrode. The third metal has a melting temperature of no greater than about 300° C. The rear region of the base substrate is in electrical communication with the second electrode via the first electrode.

The present invention also provides a method of forming the invention PV cell. The method comprises the step of applying a composition to the outer surface of the first electrode to form a layer. The rear region of the base substrate is free of physical contact with the layer. The method further comprises the step of heating the layer to a temperature of no greater than about 300° C. to form the second electrode. The composition comprises the polymer, the second metal present in the composition in a majority amount, and the third metal. The rear region of the base substrate is in electrical communication with the second electrode via the first electrode. The invention PV cell may be used for converting light of many different wavelengths into electricity.

### BRIEF DESCRIPTION OF THE DRAWINGS

The present invention may be readily appreciated, as the same becomes better understood by reference to the following detailed description when considered in connection with the accompanying drawings wherein:

FIG. 1A is a front view of an embodiment of the PV cell including a base substrate, a passivation layer, fingers, and a pair of busbars;

FIG. 1B is a rear view of the embodiment of the PV cell including the base substrate, the first electrode, and three sets of second electrodes configured as contact pads;

FIG. 2 is a partial cross-sectional side view taken along line 2-2 of FIG. 1B illustrating a rear doped region of the base substrate, the first electrode, and a second electrode;

FIG. 3 is a partial cross-sectional side view of an embodiment of the PV cell illustrating a rear doped region of a base substrate, a grid or array of first electrodes, a passivation layer, and a second electrode;

FIG. 4 is a partial cross-sectional side view of an embodiment of the PV cell illustrating a rear doped region of a base substrate, a first electrode having localized contacts, a passivation layer, and a second electrode;

FIG. 5 is a partial cross-sectional side view of an embodiment of the PV cell illustrating a base substrate having localized rear doped regions, a first electrode having localized contacts, a passivation layer, and a second electrode;

FIG. 6 is a partial cross-sectional side view of another embodiment of the PV cell as an embodiment of an emitter-wrap through (EWT) cell and illustrating a base substrate having localized rear doped regions and a wrapped doped region, first electrodes having localized contacts, a passivation layer, and a second electrode;

FIG. 7 is a partial cross-sectional side view of an embodiment of the PV cell as an embodiment of an interdigitated back contact (IBC) cell and illustrating a base substrate having localized rear doped regions, a first electrode having localized contacts, a passivation layer, and a second electrode;

FIG. 8 is a partial cross-sectional side view taken along line 2-2 of FIG. 1 illustrating another embodiment of the PV cell having an upper doped region of the base substrate, the passivation layer, fingers, and one of the busbars;

FIG. 9 is a partial cross-sectional perspective view of an embodiment of the PV cell illustrating upper and rear doped regions of a base substrate, a passivation layer, fingers, a first electrode, a pair of busbars, and a pair of second electrodes;

FIG. 10 is a diagram illustrating polymer curing and solder reflow of a composition useful for forming the second electrodes and busbars of the PV cell;

FIG. 11A is a schematic rear view of an embodiment of the PV cell including a base substrate, a first electrode defining a hole, and a second electrode disposed over the first electrode and in contact with the base substrate via the hole;

FIG. 11B is a schematic side view of the PV cell of FIG. 20A;

FIG. 12A is a schematic rear view of an embodiment of the PV cell including a base substrate, a first electrode defining a plurality of holes, and a second electrode disposed over the first electrode and in contact with the base substrate via the holes;

FIG. 12B is a schematic side view of the PV cell of FIG. 20A;

FIG. 13 is a schematic rear view of an embodiment of the PV cell including a base substrate; interdigitated fingers, and a pair of busbars;

FIG. 14 is a box graph illustrating cell efficiency (NCell) of comparative and invention examples;

FIG. 15 is a box graph illustrating open-circuit voltage (V_{OC}) of comparative and invention examples with ethylene vinyl acetate and silicone encapsulants;

FIG. 16 is a graph illustrating I-V (or I-U) characteristics of comparative and invention examples with amps (A) and volts (V);

FIG. 17 is a box graph illustrating efficiency percentage of comparative and invention examples;

FIG. 18 is another box graph illustrating J_{SC} of comparative and invention examples;

FIG. 19 is another box graph illustrating V_{OC} of comparative and invention examples;

FIG. 20 is a cross-sectional optical microscopy photograph (converted to drawing form) illustrating a tabbed busbar of the invention, a finger, and a passivation layer;

FIG. 21 is a line graph illustrating J_{SC} of comparative and invention examples after damp heat aging;

FIG. 22 is a line graph illustrating V_{OC} of comparative and invention examples after damp heat aging; and

FIG. 23 is a line graph illustrating sheet resistivity (rs) of comparative and invention examples after damp heat aging.

### DETAILED DESCRIPTION OF THE INVENTION

Referring to the Figures, wherein like numerals indicate like parts throughout the several views, an embodiment of the photovoltaic (PV) cell is generally shown at 20. PV cells 20 are useful for converting light of many different wavelengths into electricity. As such, the PV cell 20 can be used for a variety of applications. For example, a plurality of PV cells 20 can be used in a solar module (not shown). The solar module can be used in a variety of locations and for a variety of applications, such as in residential, commercial, or industrial, applications. For example, the solar module can be used to generate electricity, which can be used to power electrical devices (e.g. lights and electric motors), or the solar module can be used to shield objects from sunlight (e.g. shield automobiles parked under solar modules that are disposed over parking spaces). The PV cell 20 is not limited to any particular type of use. The figures are not drawn to scale. As such, certain components of the PV cell 20 may be larger or smaller than as depicted.

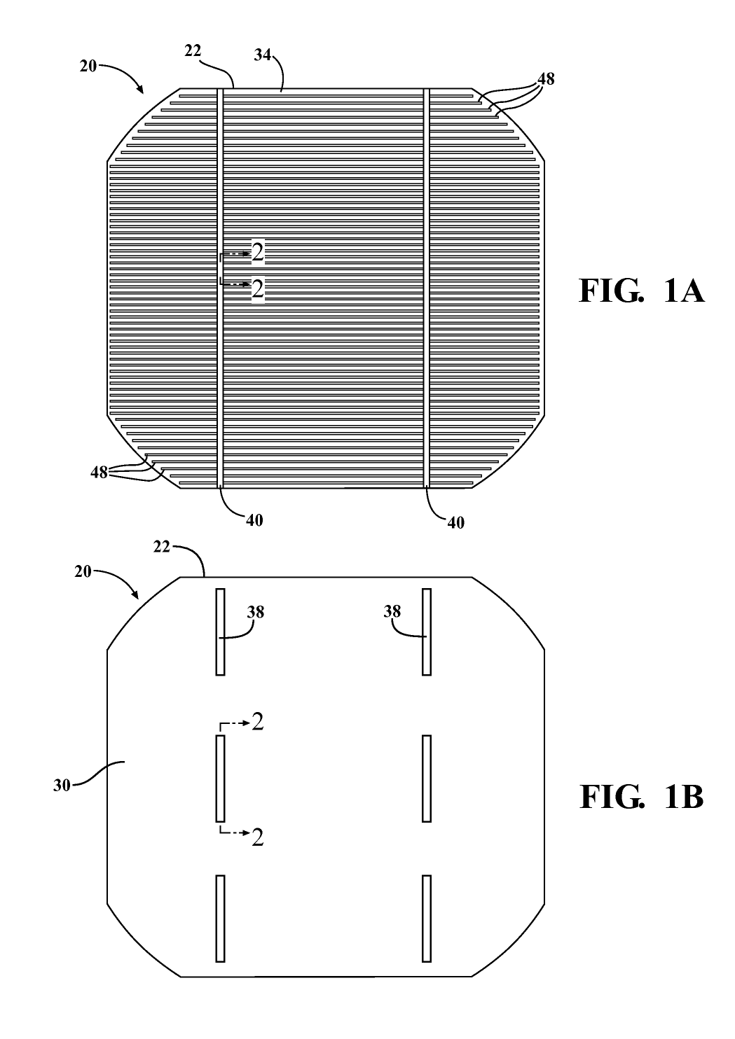

Referring to FIG. 1, the PV cell 20 is shown in a square configuration with rounded corners, i.e., a pseudo-square. While this configuration is shown, the PV cell 20 may be configured into various shapes. For example, the PV cell 20 may be a rectangle with corners, a rectangle with rounded or curved corners, a circle, etc. The PV cell 20 is not limited to any particular shape. The PV cell 20 can be of various sizes, such as 4 by 4 inch (10.2 by 10.2 cm) squares, 5 by 5 inch (12.7 by 12.7 cm) squares, 6 by 6 inch (15.2 by 15.2 cm) squares, etc. The PV cell 20 is not limited to any particular size.

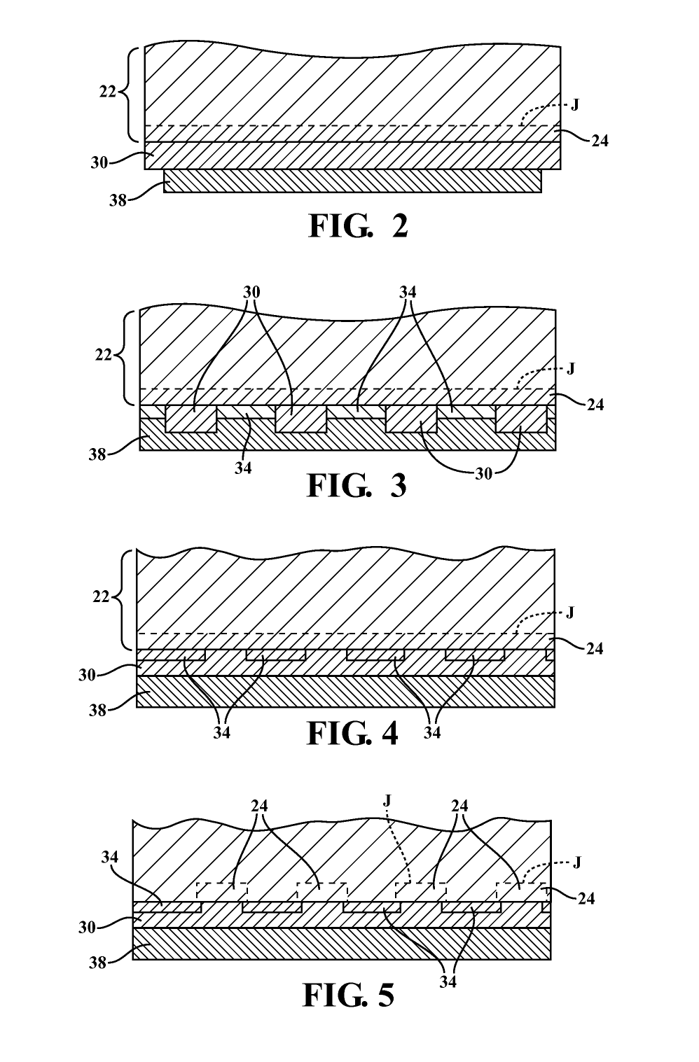

Referring to FIGS. 2 through 5, the PV cell 20 comprises a base substrate 22. The base substrate 22 comprises silicon. The silicon may also be referred to in the art as a semiconductor material. Various types of silicon can be utilized, such as monocrystalline silicon, polycrystalline silicon, amorphous silicon, or combinations thereof. In certain embodiments, the base substrate 22 comprises crystalline silicon, e.g. monocrystalline silicon. The PV cell 20 is generally referred to in the art as a wafer type PV cell 20. Wafers are thin sheets of silicon that are typically formed from mechanically sawing the wafer from a single (mono) crystal or multicrystal silicon ingot. Alternatively, wafers can be formed from casting silicon, from epitaxial liftoff techniques, pulling a silicon sheet from a silicon melt, etc.

The base substrate 22 is generally planar, but may also be non-planar. The base substrate 22 is typically classified as a p-type or an n-type, silicon substrate (based on doping). The base substrate 22, e.g. wafer, can be of various thicknesses, such as from about 1 to about 1000, about 75 to about 750, about 75 to about 300, about 100 to about 300, or about 150 to about 200, μm thick on average.

The base substrate 22 includes a rear region 24, which may also be referred to herein as a rear doped region 24 or as a rear side doped region 24. In various embodiments, the rear region 24 is free of doping and in other embodiments, the rear region 24 is doped. As such, reference to “rear region” 24 and “rear doped region” 24 are interchangeable in the description herein. In certain embodiments, the rear doped region 24 may also be referred to in the art as a back surface field (BSF). In certain embodiments, the rear doped region 24 of the base substrate 22 is an n-type doped region 24 (e.g. an n⁺ emitter layer) such that a remainder of the base substrate 22 is generally p-type. In other embodiments, the rear doped region 24 of the base substrate 22 is a p-type doped region 24 (e.g. a p⁺ emitter layer) such that a remainder of the base substrate 22 is generally n-type. In further embodiments, there are multiple rear doped regions 24 which can be combinations of one or more n-type doped regions 24a and/or one or more p-type doped regions 24b.

Referring to FIGS. 2 through 4, the base substrate 22 includes an n-type 24a or p-type 24b rear doped region 24. Referring to FIG. 5, the base substrate 22 includes localized doped regions 24. In certain embodiments, the localized doped regions 24 are n-type 24a; while in other embodiments, the regions 24 are p-type 24b.

In certain embodiments, the base substrate 22 includes an upper doped region 26 opposite the rear doped region 24. The upper doped region 26 may also be referred to as a front side doped region 26, which is generally the sun up/facing side. The upper doped region 26 may also be referred to in the art as a surface emitter, or active semiconductor, layer. In certain embodiments, the upper doped region 26 of the base substrate 22 is an n-type doped region 26a (e.g. an n⁺ emitter layer) such that a remainder of the base substrate 22 is generally p-type. In other embodiments, the upper doped region 26 of the base substrate 22 is a p-type doped region 26b (e.g. a p⁺ emitter layer) such that a remainder of the base substrate 22 is generally n-type. The upper doped region 26 can be of various thicknesses, such as from about 0.1 to about 5, about 0.3 to about 3, or about 0.4, μm thick on average. The upper doped region 26 may be applied such that doping under the fingers 48 is increased as in “selective emitter” technologies.

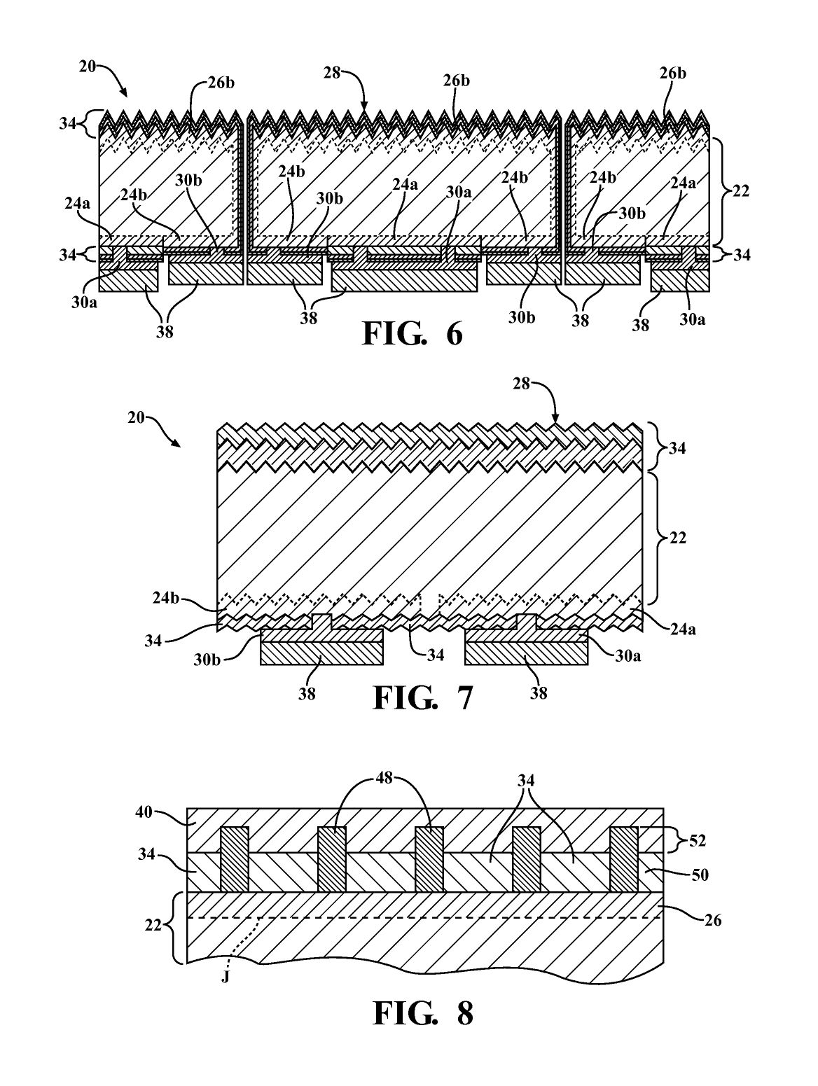

Referring to FIG. 6, the base substrate 22 includes an emitter wrap through (EWT) 26. Typically, the base substrate 22 of an EWT is p-type. The base substrate 22 includes localized doped regions 24. The rear doped regions 24 can include n-type(s) 24a and/or p-types 24b. Such PV cells 20 are generally referred to in the art as EWT cells 20. In other embodiments, the PV cell 20 can be configured as a metallic wrap through (MWT) (not shown). MWT cells generally have a plurality of fingers, and are understood in the art. Referring to FIG. 7, the base substrate 22 includes two different rear doped regions 24. Typically, one region 24 is p-type 24b and the other region is n-type 24a. Typically, the upper doped region 26 is p-type 26b, which is useful as a front surface field to mitigate charge recombination. Such PV cells 20 are generally referred to in the art as interdigitated back contact (IBC) cells 20. Some of these embodiments, as well as others, are described in detail below.

As shown in FIGS. 6 and 7, the base substrate 22 can include a textured surface 28. The textured surface 28 is useful for reducing reflectivity of the PV cell 20. The textured surface 28 may be of various configurations, such as pyramidal, inverse pyramidal, random pyramidal, isotropic, etc. Texturing can be imparted to the base substrate 22 by various methods. For example, an etching solution can be used for texturing the base substrate 22. The PV cell 20 is not limited to any particular type of texturing process.

Various types of dopants and doping methods can be utilized to form the doped regions 24,26 of the base substrate 22. For example, a diffusion furnace can be used to form an n-type doped region 24a,26a and a resulting n-p (or “p-n”) junction (J). An example of a suitable gas is phosphoryl chloride (POCl₃). In addition or alternate to phosphorus, arsenic can also be used to form n-type regions 24a,26a. At least one of the periodic table elements from group V, e.g. boron or gallium, can be used to form p-type regions 24b,26b. Elements from group III can also be used, e.g. aluminum. The PV cell 20 is not limited to any particular type of dopant or doping process.

Doping of the base substrate 22 can be at various concentrations. For example, the base substrate 22 can be doped at different dopant concentrations to achieve resistivity of from about 0.5 to about 10, about 0.75 to about 3, or about 1, Ω·cm (Ω.cm). If present, the upper doped region 26 can be doped at different dopant concentrations to achieve sheet resistivity of from about 50 to about 150, or about 75 to about 125, or about 100, Ω/□ (Ω per square). The same or similar concentrations can be used for the n-type regions 24a,26a regardless of location. In general, a higher concentration of doping may lead to a higher open-circuit voltage (V_{OC}) and lower resistance, but higher concentrations of doping can also result in charge recombination depleting cell performance and introduce defect regions in the crystal.

In certain embodiments, one of the doped regions, e.g. the upper 26, is an n-type 26a and the other doped region, e.g. the rear 24, is a p-type 24b. The opposite arrangement may also be used, i.e., the upper 26 is a p-type 26b and the rear 24, is an n-type 24a. Such configurations, where the oppositely doped region 24,26 interfaces, are referred to in the art as p-n junctions (J) and are useful for photo-excited charge separation provided there is at least one positive (p) region and one negative (n) region. Specifically, when two regions of different doping are adjacent, a boundary defined there between is generally referred to in the art as a junction. When the doping are of opposite polarities then the junction (J) is generally referred to as a p-n junction (J). When doping is merely of different concentrations, the “boundary” may be referred to as an interface, such as an interface between like regions, e.g. p and p⁺ regions. As shown generally in the Figures, such junctions (J) may be optional, depending on what type of doping is utilized in the base substrate 22. The PV cell 20 is not limited to any particular number or location of junction(s) (J). For example, the PV cell 20 may only include one junction (J), at the front or the rear.

Other constructs can also be used, as like shown in FIGS. 6 and 7, where the rear regions 24a,24b are adjacent one another. Various combinations of the rear region(s) 24a,24b, and optionally, upper region(s) 26a,26b, at various locations, can be utilized.

A first electrode 30 is disposed on and in electrical contact with the rear doped region 24. The first electrode 30 has an outer surface 32. The first electrode 30 may cover the entire rear doped region 24 or only a portion thereof. If the later, typically a passivation layer 34 is used to protect exposed portions of the rear doped region 24, but the passivation layer 34 is not used between the first electrode 30 and the portion of rear doped region 24 in direct physical and electrical contact.

The passivation layer 34 may be formed from various materials. In certain embodiments, the passivation layer 34 comprises SiO_{X}, ZnS, MgF_{X}, SiN_{X}, SiCN_{X}, AlO_{X}, TiO₂, a transparent conducting oxide (TCO), or combinations thereof. Examples of suitable TCOs include doped metal oxides, such as tin-doped indium oxide (ITO), aluminum-doped zinc-oxide (AZO), indium-doped cadmium-oxide, fluorine-doped tin oxide (FTO), or combinations thereof. In certain embodiment, passivation layer 34 comprises SiN_{X}. Employing SiN_{X} is useful due to its excellent surface passivation qualities. Silicon nitride is also useful for preventing carrier recombination at the surface of the PV cell 20.

As best shown in FIGS. 6 and 7, the passivation layer 34 is disposed on the upper doped region 26. In this location, the passivation layer 34 is useful for increasing sunlight absorption by the PV cell 20, e.g. by reducing reflectivity of the PV cell 20, as well as generally improving wafer lifetime through surface and bulk passivation. The passivation layer 34 has an outer surface 36 opposite the upper doped region 26. The passivation layer 34 may also be referred to in the art as a coating, a dielectric passivation, or an anti-reflective coating (ARC), layer.

The passivation layer 34 may be formed from two or more sub-layers, such that the passivation layer 34 may also be referred to as a stack. Such sub-layers can include a bottom ARC (B-ARC) layer and/or a top ARC (T-ARC) layer. Examples of B-ARC and T-ARC layers 34 are shown in FIGS. 6 and 7. Such sub-layers can also be referred to as dielectric layers, and be formed from the same or different material. For example, there may be two or more sub-layers of SiN_{X}; a sub-layer of SiN_{X} and a sub-layer of AIO_{X}; etc. The layers 34 can be in various orders.

The passivation layer 34 can be formed by various methods. For example, the passivation layer 34 can be formed by using a plasma-enhanced chemical vapor deposition (PECVD) process. In embodiments where the passivation layer 34 comprises SiN_{X}, silane, ammonia, and/or other precursors can be used in a PECVD furnace to form the passivation layer 34. The passivation layer 34 can be of various thicknesses, such as from about 10 to about 150, about 50 to about 90, or about 70, nm thick on average. Sufficient thickness can be determined by the refractive indices of the coating material and base substrate 22. The PV cell 20 is not limited to any particular type of coating process.

The first electrode 30 may take the form of a layer (e.g. FIG. 2), a layer having localized contacts (e.g. FIGS. 4 and 5), or a contact grid comprising fingers, dots, pads, and/or busbars (e.g. FIG. 3). Examples of suitable configurations include p-type base configurations, n-type base configurations, PERC or PERL type configurations, bifacial BSF type configurations, heterojunction with intrinsic thin layer (HIT) configurations, etc.

The PV cell 20 is not limited to any particular type of electrode 30 or electrode configuration. The first electrode 30 can be of various thicknesses, such as from about 0.1 to about 500, about 1 to about 100, or from about 5 to about 50, μm thick on average.

In embodiments where the rear doped region 24 is a p-type 24b (or includes at least one p-type region 24b), the first electrode 30 typically comprises at least one of the periodic table elements of group III, e.g. aluminum (Al). Al can be used as a p-type dopant. For example, an Al paste can be applied to the base substrate 22 and then fired to form the first electrode 30, while also forming the rear p⁺-type doped region 24b. The Al paste can be applied by various methods, such as by a screen printing process. The first electrode 30 can also be formed via electrochemical or physical vapor deposition (PVD). Other suitable methods are described below.

In embodiments where the rear doped region 24 is an n-type 24a (or includes at least one n-type region 24a), the first electrode 30 typically comprises silver (Ag). Ag pastes can include n-type dopants such as phosphorous can be used to apply localized doped regions 24a. For example, an Ag paste can be applied to the base substrate 22 and then fired to form the first electrode 30, while also forming the rear n-type doped region 24a. The Ag paste can be applied by various methods, such as by a screen printing process. Other suitable methods are described below.

A combination of different electrodes 30 can be utilized. For example. the PV cell 20 can include one or more electrodes 30 formed from one metal, e.g. Al, and one or more electrodes 30 formed from a different metal, e.g. Ag. As shown in FIGS. 6 and 7, there are multiple electrodes 30, with each electrode 30 generally associated with a rear region 24a,24b. Often, Ag electrodes 30a are in electrical contact with n-type regions 24a, and Al electrodes 30b are in electrical contact with p-type regions 24b.

The first electrode 30 comprises a first metal, which is present in (each of) the first electrode(s) 30 in a majority amount. The first metal may comprise various types of metals. In certain embodiments, the first metal comprises Al. In other embodiments, the first metal comprises Ag. In yet other embodiments, the first metal comprises a combination of Ag and Al. By “majority amount”, it is generally meant that the first metal is the primary component of the first electrode 30, such that it is present in an amount greater than any other component that may also be present in the first electrode 30. In certain embodiments, such a majority amount of the first metal, e.g. Al and/or Ag, is generally greater than about 35, greater than about 45, or greater than about 50, weight percent (wt %), each based on the total weight of the first electrode 30.

As best shown in FIG. 2, a second electrode 38 is spaced from the rear doped region 24 of the base substrate 22. The rear doped region 24 is free of (direct) physical contact with the second electrode 38. The second electrode 38 is in electrical contact with the first electrode 30. The second electrode 38 need only contact a portion of the first electrode 30, or it can cover an entirety of the first electrode 30. The first and second electrodes 30,38 may be referred to in the art as an electrode stack. The rear doped region 24 is in electrical communication with the second electrode 38 via the first electrode 30. The second electrode 38 is typically configured in the shape of a pad(s) 38, contact pad(s) 38, or busbar(s) 38. Reference to the second electrode 38 herein can refer to various configurations.

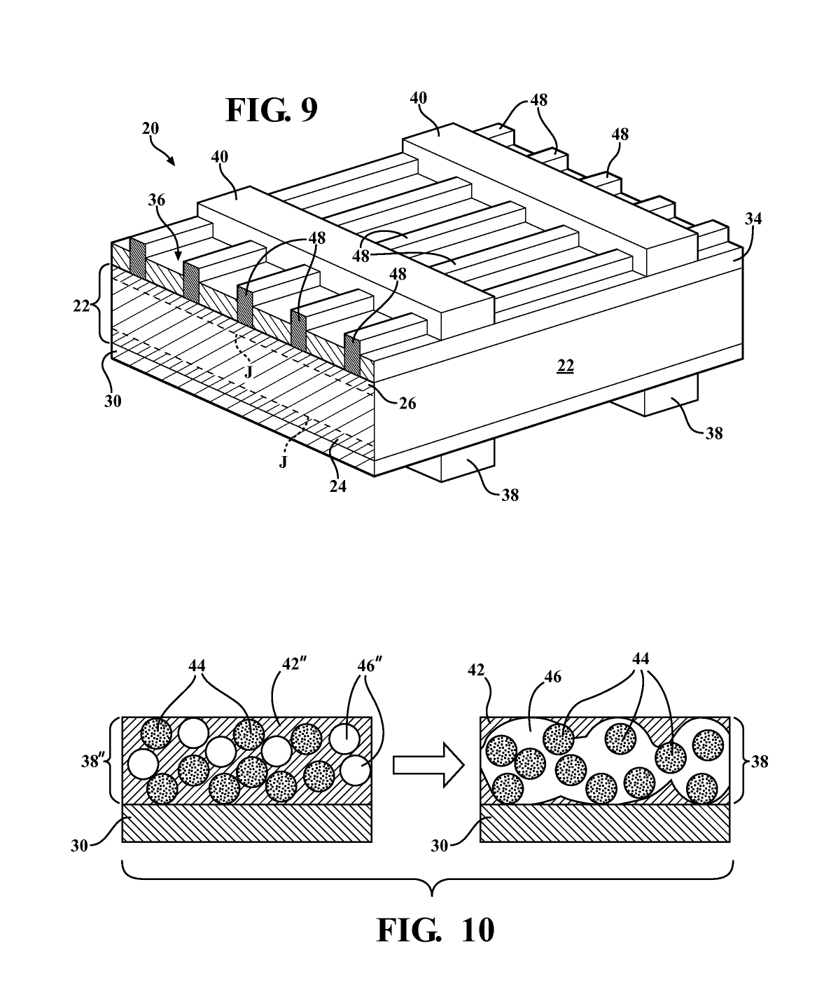

For example, as best shown in FIG. 9, the PV cell 20 can include a pair of second electrodes 38, shaped as busbars 38, on the first electrode 30. In addition, a pair of front busbars 40 is disposed opposite the second electrodes 38 in generally a mirror configuration. The second electrodes 38 and the busbars 40 can be the same or different from each other, both in chemical makeup and/or in physical characteristic, such as shape and size. The busbars 40 are described further below.

As shown in FIGS. 7 and 9, the PV cell 20 can have two second electrodes 38. In certain embodiments, the PV cell 20 may have more than two second electrodes 38 (e.g. FIG. 6), such as three second electrodes 38, four second electrodes 38, six second electrodes 38, etc. Each second electrode 38 is in electrical contact with at least one electrode 30. The second electrodes 38 are useful for collecting current from the first electrode 30 which has collected current from the rear doped region 24. As shown generally, the second electrode 38 is disposed directly on the outer surface 32 of the first electrode 30 to provide intimate physical and electrical contact thereto. This places the second electrode 38 in position for carrying current directly from the first electrode 30. The first electrode 30 is in intimate physical and electrical contact with the rear doped region 24 of the base substrate 22.

The second electrode 38 can be of various widths, such as from about 0.5 to about 10, about 1 to about 5, or about 2, mm wide on average. The second electrode 38 can be of various thicknesses, such as from about 0.1 to about 500, about 10 to about 250, about 30 to about 100, or about 30 to about 50, μm thick on average. The second electrode 38 can be spaced various distances apart.

The second electrode 38 comprises a polymer 42, or a monomer which is polymerisable to yield the polymer 42. The polymer 42 can be of various types. The polymer 42 is generally formed from a thermosetting resin, such as an epoxy, an acrylic resin, silicone, a polyurethane, or combinations thereof. Typically, the polymer 42 is formed in the presence of a cross-linking agent and/or a catalyst for promoting cross-linking of the polymer 42. The cross-linking agent can be selected from carboxylated polymers, dimer fatty acids and trimer fatty acids. Other additives can be included, such as dicarboxylic and/or monocarboxylic acids, adhesion promoters, defoamers, fillers, etc. Further examples of suitable polymers, cross-linking agents, and catalysts, are disclosed in U.S. Pat. No. 6,971,163 to Craig et al. (the '163 patent), and U.S. Pat. No. 7,022,266 to Craig (the '266 patent), which are incorporated herein by reference in their entirety to the extent they do not conflict with the general scope of the invention.

The second electrode 38 further comprises a second metal 44, which is present in the second electrode 38 in a majority amount. The “second” is used to differentiate the metal of the second electrode 38 from the “first” metal of the first electrode 30, and does not imply quantity or order. The second metal may comprise various types of metals. In certain embodiments, the second metal of the second electrode 38 is the same as the first metal of the first electrode 30. For example, both the first and second metals can be Ag. In other embodiments, the second metal of the second electrode 38 is different from the first metal of the first electrode 30. In these embodiments, the first metal typically comprises Al and the second metal typically comprises Cu. In other embodiments, the first metal comprises Ag and the second metal comprises Cu. In yet other embodiments, the first metal comprises Ag and the second metal comprises Ag. In yet further embodiments, the first metal comprises a combination of Ag and Al (with the combination being present in a majority amount), and the second metal comprises Cu. By “majority amount”, it is generally meant that the second metal is the primary component of the second electrode 38, such that it is present in an amount greater than any other component that may also be present in the second electrode 38. In certain embodiments, such a majority amount of the second metal, e.g. Cu, is generally greater than about 25, greater than about 30, greater than about 35, or greater than about 40, wt %, each based on the total weight of the second electrode 38.

The second electrode 38 further comprises a third metal 46. The third metal is different from the first metal of the first electrode 30. The third metal is also different from the second metal of the second electrode 38. Typically, the metals are different elements, rather than just different oxidation states of the same metal. The “third” is used to differentiate the metal of the second electrode 38 from the “first” metal of the first electrode 30, and does not imply quantity or order. The third metal melts at a lower temperature than melting temperatures of the first and second metals. Typically, the third metal has a melting temperature of no greater than about 300, no greater than about 275, or no greater than about 250, ° C. Such temperatures are useful for forming the second electrode 38 at low temperatures as described further below.

In certain embodiments, the third metal comprises solder. The solder can comprise various metals or alloys thereof. One of these metals is typically tin (Sn), lead, bismuth, cadmium, zinc, gallium, indium, tellurium, mercury, thallium, antimony, Ag, selenium, and/or an alloy of two or more of these metals. In certain embodiments, the solder comprises a Sn alloy, such as a eutectic alloy, e.g. Sn63/Pb37. In certain embodiments, the solder powder comprises two different alloys, such as a Sn alloy and a Ag alloy, alternatively more than two different alloys. The third metal can be present in the second electrode 38 in various amounts, typically in an amount less than the second metal.

The rear doped region 24 of the base substrate 22 is free of (direct) physical contact with the second electrode 38. Specifically, the first electrode 30 (and optionally, the passivation layer 34) serves as a “barrier” between the second electrode 38 and rear doped region 24. Without being bound or limited by any particular theory, it is believed that physical separation of the second electrode 38 and the rear doped region 24 is beneficial. Specifically, such separation prevents diffusion of the second metal, e.g. Cu, into the base substrate 22. It is believed that preventing such diffusion prevents the opposite doped region 24 from being shunted by the second metal of the second electrode 38. Reducing the area of contact between the base substrate 22 and the second electrode 38 is also useful for reducing loss due to minority carrier recombination.

In certain embodiments, a plurality of fingers 48 are spaced from each other and disposed in the passivation layer 34. Each of the fingers 48 has a lower portion 50 in electrical contact with the upper doped region 26 of the base substrate 22. The lower portion 38 in actual electrical contact may be quite small, such as tips/ends of the fingers 36. Each of the fingers 48 also has an upper portion 52 opposite the lower portion 50 extending outwardly through the outer surface 32 of the passivation layer 34. The fingers 48 are generally disposed in a grid pattern, as best shown in FIGS. 1 and 9. Typically, the fingers 48 are disposed such that the fingers 48 are relatively narrow while being thick enough to minimize resistive losses. Orientation and number of the fingers 48 may vary. In other embodiments, similar “fingers” may define a series of first electrodes 30 on the rear of the PV cell 20, in addition, or alternate to the fingers 48 on the front of the PV cell 20. Such first electrodes 30 can be of similar shape, makeup, and/or composition as the fingers 48.

The fingers 48 can be of various widths, such as from about 10 to about 200, about 70 to about 150, about 90 to about 120, or about 100, μm wide on average. The fingers 48 can be spaced various distances apart from each other, such as from about 1 to about 5, about 2 to about 4, or about 2.5, mm apart on average. The fingers 48 can be of various thicknesses, such as from about 5 to about 50, about 5 to about 25, or about 10 to about 20, μm thick on average.

Each of the fingers 48 comprises a metal, which is present in each of the fingers 48 in a majority amount. The metal may comprise various types of metals. In certain embodiments, the metal comprises silver (Ag). In other embodiments, the metal comprises copper (Cu). By “majority amount”, it is generally meant that the metal is the primary component of the fingers 48, such that it is present in an amount greater than any other component that may also be present in the fingers 48. In certain embodiments, such a majority amount of the metal, e.g. Ag, is generally greater than about 35, greater than about 45, or greater than about 50, wt %, each based on the total weight of the finger 48.

The fingers 48 can be formed by various methods. Suitable methods include plating; sputtering; vapor deposition; strip or patch coating; ink-jet printing, screen printing, gravure printing, letter printing, thermal printing, dispensing or transfer printing; stamping; electroplating; electroless plating; or combinations thereof. In certain embodiments, the fingers 48 are formed via an etching/firing process. Suitable compositions for forming the fingers 48 include fritted Ag pastes.

Various types of fritted or unfritted Ag or Al pastes can be used to form the fingers 48. Such pastes generally include an organic carrier. Upon high temperature processing or “firing”, the organic carrier burns out and is removed from the bulk composition. Ag particles are dispersed throughout the carrier. A solvent may be included to adjust rheology of the paste. The fritted paste includes glass frits, which generally comprises PbO, B₂O₃, and SiO₂. Examples of suitable fritted Ag pastes are commercially available from Ferro of Mayfield Heights, Ohio and Heraeus Materials Technology, LLC of West Conshohocken, Pa. Other components may also be used in addition or alternate to leaded glass, such as unleaded or low leaded glass.

In other embodiments, the fingers 48 are formed by a plating process (rather than an etching/firing process). In these embodiments, the fingers 48 generally comprise a plated or stacked structure (not shown). For example, the fingers 48 can comprise two or more of the following layers: nickel (Ni), Ag, Cu, and/or Sn. The layers can be in various orders, provided the Cu layer (if present) is not in direct physical contact with the upper doped region 26 of the base substrate 22. Typically, a seed layer comprising Ag or a metal other than Cu, e.g. Ni, is in contact with the upper doped region 26. In certain embodiments, the seed layer comprises Ni silicide. Subsequent layers are then disposed on the seed layer to form the fingers 48. When the fingers 48 include Cu, a passivation layer such as Sn or Ag is disposed over the Cu layer to prevent oxidation. In certain embodiments, the lower portions 50 of the fingers 48 comprise Ni, the upper portions 52 of the fingers 48 comprise Sn, and Cu is disposed between the Ni and Sn. In this way, the Cu is protected from oxidation by the Ni, Sn, and surrounding passivation layer 34. Such layers can be formed by various methods, such as aerosol printing and firing; electrochemical deposition; etc. The PV cell 20 is not limited to any particular type of process of forming the fingers 48.

In certain embodiments, the PV cell 20 includes one or more busbars 40 opposite the second electrode(s) 38. Referring to FIG. 8, the busbar 40 is spaced from the upper doped region 26 of the base substrate 22. As shown in FIGS. 1 and 9, the PV cell 20 generally has two busbars 40. In certain embodiments, the PV cell 20 may have more than two busbars 40 (not shown), such as three busbars 40, four busbars 40, six busbars 40, etc. Each busbar 40 is in electrical contact with the upper portions 52 of the fingers 48. The busbars 40 are useful for collecting current from the fingers 48 which have collected current from the upper doped region 26. As best shown in FIG. 9, each of the busbars 40 is disposed on the outer surface 36 of the passivation layer 34 and around each of the fingers 48 to provide intimate physical and electrical contact to the upper portions 52 of the fingers 48. Such contact places the busbar 40 in position for carrying current directly from the fingers 48. Typically, the busbar 40 is transverse the fingers 48. Said another way, the busbar 40 can be at various angles relative to the fingers 48, including perpendicular. The fingers 48 themselves are in intimate physical and electrical contact with the upper doped region 26 of the base substrate 22.

The busbar 40 can be of various widths, such as from about 0.5 to about 10, about 1 to about 5, or about 2, μm wide on average. The busbar 40 can be of various thicknesses, such as from about 0.1 to about 500, about 10 to about 250, about 30 to about 100, or about 30 to about 50, μm thick on average. The busbars 40 can be spaced various distances apart. Typically, the busbars 40 are spaced to divide lengths of the fingers 48 into ˜equal regions, e.g. as shown in FIG. 1.

The busbar 40 can comprise various metals. In certain embodiments, the busbar 40 comprises the second metal, which is present in the busbar 40 in a majority amount. The second metal is as described and exemplified above. By “majority amount”, it is generally meant that the second metal is the primary component of the busbar 40, such that it is present in an amount greater than any other component that may also be present in the busbar 40. In certain embodiments, such a majority amount of the second metal, e.g. Cu, is generally greater than about 25, greater than about 30, greater than about 35, or greater than about 40, wt %, each based on the total weight of the busbar 40. In certain embodiments, the busbar 40 also generally comprises the third metal. The third metal is as described and exemplified above.

As best shown in FIG. 8, the upper doped region 26 of the base substrate 22 is free of (direct) physical contact with the busbar 40. Specifically, the passivation layer 34 serves as a barrier between the busbar 40 and upper doped region 26. Without being bound or limited by any particular theory, it is believed that physical separation of the busbar 40 and the upper doped region 26 is beneficial for at least two reasons. First, such separation prevents diffusion of the second metal, e.g. Cu, into the upper doped region 26. It is believed that preventing such diffusion prevents the upper doped region 26, e.g. the p-n junction (J), from being shunted by the second metal of the busbar 40. Second, such physical separation is believed to reduce minority carrier recombination at the metal and silicon interfaces. It is believed that by reducing the area of metal/silicon interface, loss due to recombination is generally reduced and open-circuit voltage (V_{OC}) and short-circuit current density (J_{SC}) are generally improved. The area is reduced due to the passivation layer 34 being disposed between much of the busbar 40 and the upper doped region 26, with the fingers 48 being the only metal components in contact with the upper doped region 26 of the base substrate 22. In certain embodiments, such as shown in FIGS. 6 and 7, the PV cell 20 is free of such fingers 48 and busbars 40, i.e., the PV cell 20 is free of a front grid. Additional embodiments of the PV cell 20 will now be described immediately below.

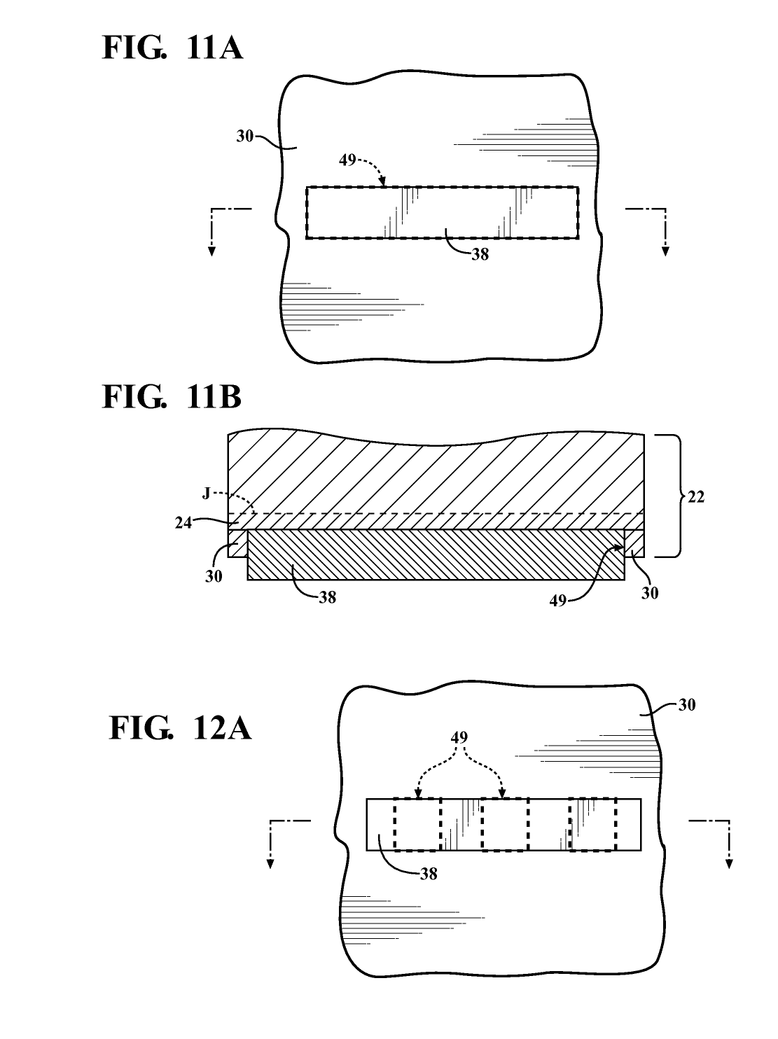

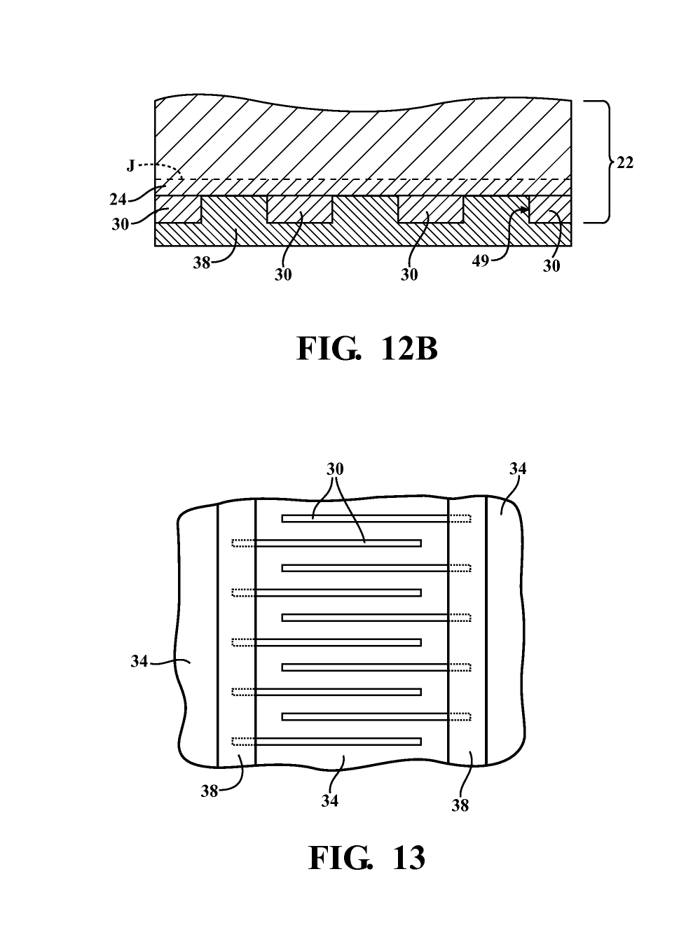

The PV cells 20 of FIGS. 11 and 12 are similar to that of FIG. 1B. In FIG. 11, the first electrode 30 defines a hole 49, whereas in FIG. 12, the first electrode 30 defines a plurality of holes 49. The hole(s) 49 is/are also defined by the passivation layer 34, if present. The second electrode 38 is disposed over the first electrode 30 and is in electrical contact with the base substrate 22 via the hole(s) 49. The base substrate 22 may or may not include doping 24 proximal the hole(s) 49. The base substrate 22 can be in direct contact with the second electrode 38. When the second electrode 38 is formed from the invention composition, the solder can prevent the possibility of the metal powder, e.g. Cu, leaching/migrating into the base substrate 22, e.g. Si. By utilizing the holes 49, cost of manufacture can be reduced. Alternatively, a dielectric passivation layer 34 may be between the Cu electrode 38 and the substrate 22. A possible benefit of a passivation layer 34 is an improved reduction in charge recombination resulting in improved cell 20 efficiency.

The PV cell 20 of FIG. 13 is of an interdigitated back contact (IBC) configuration, with interdigitated fingers 30, and a pair of busbars 38. The busbars 38 can be formed from the invention composition, e.g. Cu or Cu-based, whereas the fingers 30 can be formed from another material, e.g. Ag or Ag-based. Such IBC configurations are understood in the art.

The present invention also provides a method of forming the PV cell 20. The method includes the step of applying a composition to the outer surface 32 of the first electrode 30 to form a layer 38″. As used herein, a quotation mark (″) generally indicates a different state of the respective component, such as prior to curing, prior to sintering, etc. The composition can be applied by various methods, as alluded to above. In certain embodiments, the composition is printed on at least a portion of the outer surface 32 of the first electrode 30 to form a layer 38″. Various types of deposition methods can be utilized, such as printing through screen or stencil, or other methods such as aerosol, ink jet, gravure, or flexographic, printing. In certain embodiments, the composition is screen printed directly onto the outer surface 32 of the first electrode 30 to define the second electrode 38. The rear doped region 24 of the base substrate 22 is free of (direct) physical contact with the layer 38″. The composition can be applied to the outer surface 32 of the first electrode 30 to make direct physical and electrical contact to the first electrode 30 with the layer 38″.

As alluded to above, the invention composition used to form the layer 38″ (eventually the second electrode 38) comprises the polymer 42″, the second metal 44″ present in the composition in a majority amount, and the third metal 46″. Such components and amounts are as described above. In certain embodiments, various types of Cu pastes can be used as the composition to form the layer 38″. In certain embodiments, the composition comprises a copper powder 44 as the second metal, and a solder powder 46″ as the third metal. The solder powder 46″ melts at lower temperature than melting temperature of the copper powder 44. The composition further comprises the polymer 42″, or a monomer which is polymerisable to yield the polymer 42″. The composition can further comprise the cross-linking agent for the polymer 42″ and/or the catalyst for promoting cross-linking of the polymer 42″. The composition can also include fluxing agents, which may react to form a catalyst for cross-linking of the polymer 42″. The composition may also include a solvent to adjust rheology. Other additives can be also included, such as dicarboxylic and/or monocarboxylic acids, adhesion promoters, defoamers, fillers, etc. Further examples of such components for forming Cu pastes useful as the composition, such as polymers, fluxing agents, solder powders, and other additives, are disclosed in the '266 patent.

The method further comprises the step of heating the layer 38″ to a temperature of no greater than about 300° C. to form the second electrode 38. The layer 38″ is generally heated to a temperature of from about 150 to about 300, about 175 to about 275, about 200 to about 250, or about 225, ° C. In certain embodiments, the layer 38″ is heated at about 250° C. or less to form the second electrode 38. Such temperatures generally sinter the third metal (e.g. solder) in the layer 38″, but do not sinter the second metal (e.g. Cu) in the layer 38″ to form the second electrode 38. Such heating may also be referred to in the art as reflow or sintering.

Referring to FIG. 10, it is believed that the particles of solder 46 sinter and coat particles of Cu 44 during heating of the layer 38″ to form the second electrode 38. Also during this time, the polymer 42″ can lose volatiles and crosslinks to a final cured state 42, generally providing adhesion to the first electrode 30 and/or other components. Such coating enables the solder coated Cu 44 to carry current of the PV cell 20, and can also prevent oxidation of the Cu 44. Due to the lower temperatures, the Cu 44 does not generally sinter during the heating, based on it having a melting temperature of about 1000° C. The low temperature of this heating step generally allows for the use of temperature sensitive base substrates 22, e.g. amorphous silicon.

The layer 38″ can be heated for various amounts of time to form the second electrode 38. Typically, the layer 38″ is heated only for the period of time required for the second electrode 38 to form. Such times can be determined via routine experimentation. An inert gas, e.g. a nitrogen (N₂) gas blanket, can be used to prevent premature oxidation of the Cu 44 prior to being coated with the solder 46″. Unnecessarily overheating the second electrode 38 for longer periods of time may damage the doped regions 24a,24b or other components of the PV cell 20 including the second electrode 38.

In certain embodiments, prior to forming the second electrode 38, the method comprises the step of applying a metallic composition to the rear doped region 24 of the base substrate 22 to form the first electrode 30. The metallic composition can comprise various components, such as those suitable for forming the first electrode 30 described above. The metallic composition can be applied by various methods, as introduced above. For example, an Al and/or Ag paste can be printed on the rear doped region 24 and fired form the first electrode 30. Different metallic compositions can be applied to different portions of the rear doped region 24, to form different electrodes 30, such as Ag pastes in certain portions to form Ag electrodes 30 and Al pastes in other portions to form Al electrodes 30.

In certain embodiments, prior to forming the second electrode 38, the method comprises the step of applying a coating composition to the rear doped region 24 of the base substrate 22 to form the passivation layer 34. The coating composition can comprise various components, such as those suitable for forming the passivation layers 34 described above. The coating composition can be applied by various methods, as introduced above. For example, a PECVD process can be utilized. In embodiments where the passivation layer 34 comprises SiN_{X}, silane, ammonia, and/or other precursors can be used in a PECVD furnace to form the passivation layer 34.

In certain embodiments, the passivation layer 34 must be “opened” by some means, e.g. by wet chemical etching or laser ablation. In other embodiments, the passivation layer 34 may be deposited in such a way that openings remain after deposition. Prior to forming the first electrode 30, doping may be imparted to the base substrate 22, prior to or after formation of the passivation layer 34.

The second electrode 38 is directly solderable, which is useful for tabbing multiple PV cells 20 together, such as by attaching ribbons or interconnects to the second electrodes 38 of the PV cells 20. Said another way, typically there is no topcoat, protective, or outermost layer which needs to be removed from the second electrode 38 prior to soldering directly thereto. This provides for reduced manufacturing time, complexity, and cost. For example, tabbing 50 can be directly soldered to the second electrode 38 without the need for additional steps to be taken. In certain embodiments, an exception to this may be an additional fluxing step. In general, a surface is directly solderable if solder can be wet out on the surface after processing. For example, if one can either directly solder a wire to a substrate (within a commercially reasonable time frame and typically using an applied flux), use a tinned soldering iron to place a solder layer on the busbar, or simply heat up the substrate and see the solder wet out the electrode surface, the material would be directly solderable. In the case of a non-solderable system, even after applying flux and extensive heating, the solder never wets the surface, and no solder joint can be made.

Further embodiments of various types of PV cells 20 utilizing the invention composition to form one or more structures/components, such as conductors, electrodes, and/or busbars formed from the invention composition, are described in co-pending PCT application Ser. No. ______(Attorney Docket No. DC11370 PSP1; 071038.01091), filed concurrently with the subject application, the disclosure of which is incorporated by reference in its entirety to the extent it does not conflict with the general scope of the present invention.

In the embodiments immediately above and in other embodiments described herein, the invention composition generally comprises: a metal powder; a solder powder which has a lower melting temperature than a melting temperature of the metal powder; a polymer; a carboxylated-polymer different from the polymer for fluxing the metal powder and cross-linking the polymer; a dicarboxylic acid for fluxing the metal powder; and a monocarboxylic acid for fluxing the metal powder. The composition can optionally further comprise additives, such as a solvent and/or an adhesion promoter.

The metal powder can comprise copper, and the solder powder can have a melting temperature of no greater than about 300° C. The solder powder can comprise at least one of a tin-bismuth (SnBi) alloy, a tin-silver (SnAg) alloy, or combinations thereof. In specific embodiments, the solder powder comprises at least one tin (Sn) alloy and no greater than 0.5 weight percent (wt %) of: mercury, cadmium, and/or chromium; and/or lead.

In various embodiments, the metal and solder powders are collectively present in an amount of from about 50 to about 95 wt %; the metal powder is present in an amount of from about 35 to about 85 wt %; and/or the solder powder is present in any amount of from about 25 to about 75 wt %; each based on the total weight of the composition.

The polymer can comprise an epoxy resin, and the carboxylated-polymer can comprise an acrylic polymer, such as a styrene-acrylic copolymer. In various embodiments, the polymer and the carboxylated-polymer are collectively present in an amount of from about 2.5 to about 10 wt %; the polymer is present in an amount of from about 0.5 to about 5 wt; and/or the carboxylated-polymer is present in an amount of from about 1 to about 7.5 wt %; each based on the total weight of the composition. In certain embodiments, the polymer and the carboxylated-polymer are in a weight ratio of from about 1:1 to about 1:3 (polymer:carboxylated-polymer).

The dicarboxylic acid can be dodecanedioic acid (DDDA) and the monocarboxylic acid can be neodecanoic acid. In various embodiments, the dicarboxylic acid present in an amount of from about 0.05 to about 1 wt %; and/or the monocarboxylic acid is present in an amount of from about 0.25 to about 1.25 wt %; each based on the total weight of the composition. Additional aspects of these compositions can be appreciated with reference to the co-pending application.

As introduced above, the PV cell 20 may be used in various applications. In certain embodiments, the tabbing is directly solderable to the second electrodes 38 of the PV cells 20. In other embodiments, additional solder (not shown) may be used between the second electrodes 38 and tabbing. Fluxing means may be used to aid in soldering, such a flux pen or flux bed. The tabbing itself may also include flux, such as Sn or Sn alloys and flux. The tabbing can be formed from various materials, such as Cu, Sn, etc. Such tabbing can be used to connect a series of PV cells 20. For example, a PV cell module (not shown) can include a plurality of the PV cells 20. Tabbing, e.g. ribbon, is generally in physical contact with the second electrode 38 of the PV cells 20 to electrically connect the PV cells 20 in series. The tabbing 50 may also be referred to in the art as an interconnection. The PV module may also include other components, such as tie layers, substrates, superstrates, and/or additional materials that provide strength and stability. In many applications, the PV cells 20 are encapsulated to provide additional protection from environmental factors such as wind and rain.

The following examples, illustrating the PV cell 20 and the method of the present invention, are intended to illustrate and not to limit the invention. The amount and type of each component used to form the compositions is indicated in Tables 1 through 3 below with all values in wt % based on a total weight of the respective composition unless otherwise indicated.

TABLE 1

| Component | Example | | |
|---|---|---|---|
| (wt %) | 1 | 2 | 3 |
| Second Metal 1 | 12.80 | 23.45 | 40.25 |
| Second Metal 2 | 34.63 | 26.81 | — |
| Third Metal 1 | 17.27 | 16.23 | 21.00 |
| Third Metal 2 | 12.10 | — | 23.76 |
| Third Metal 3 | 11.31 | 23.75 | — |
| Polymer 1 | 1.71 | 1.72 | — |
| Polymer 2 | — | — | — |
| Polymer 3 | 3.60 | 3.64 | 3.64 |
| Polymer 4 | — | — | 6.95 |
| Additive 1 | 1.98 | — | — |
| Additive 2 | — | 0.28 | 0.28 |
| Additive 3 | 1.00 | — | — |
| Additive 4 | 1.80 | 1.82 | 1.82 |
| Additive 5 | — | 0.48 | 0.48 |
| Additive 6 | 1.80 | 1.82 | 1.82 |
| Total | 100 | 100 | 100 |

Second Metal 1 is copper powder, commercially available from Mitsui Mining & Smelting Co. of Japan.

Second Metal 2 is a conventional silver powder, commercially available from Ferro.

Third Metal 1 is a Sn42/Bi58 alloy, having a melting temperature of about 138° C., commercially available from Indium Corporation of America of Elk Grove Village, Ill.

Third Metal 2 is a Sn63/Pb37 alloy, having a melting temperature of about 183° C.

Third Metal 3 is a Sn96.5/Ag3.5 alloy, having a melting temperature of about 221° C., commercially available from Indium Corporation of America.

Polymer 1 is a solid epoxy resin comprising the reaction product of epichlorohydrin and bisphenol A and having an epoxy equivalent weight (EEW) of 500-560 g/eq, commercially available from Dow Chemical of Midland, Mich.

Polymer 2 is a silicone commercially available from Dow Corning Corp. of Midland, Mich.

Polymer 3 is a low molecular weight styrene-acrylic copolymer having an acid value of about 238, on solids, commercially available from BASF Corp. of Florham Park, N.J.

Polymer 4 is a polyurethane resin commercially available from BASF Corp.

Additive 1 is a monoterpene alcohol, commercially available from Sigma Aldrich of Chicago, Ill.

Additive 2 is a styrene dibromide, commercially available from Sigma Aldrich.

Additive 3 is dodecanedioic acid, commercially available from Sigma Aldrich.

Additive 4 is propylene glycol, commercially available from Sigma Aldrich.

Additive 5 is neodecanoic acid, commercially available from Hexion Specialty Chemicals of Carpentersville, Ill.

Additive 6 is benzyl alcohol, commercially available from Sigma Aldrich.

Additive 7 is a titanate adhesion promoter, commercially available from Kenrich Petrochemicals Co.

Additive 8 is a silane adhesion promoter comprising 2-(3,4-epoxycyclohexyl) ethyltrimethoxysilane, commercially available from Dow Corning Corp.

Additive 9 is a butyl carbitol, commercially available from Dow Chemical.

TABLE 2

| Component | Example | | | |
|---|---|---|---|---|
| (wt %) | 4 | 5 | 6 | 7 |
| Second Metal 1 | 46.45 | 47.72 | 46.5600 | 47.83 |
| Second Metal 2 | — | — | — | — |
| Third Metal 1 | — | 15.63 | 16.2283 | 20.55 |
| Third Metal 2 | 40.01 | — | — | 20.45 |
| Third Metal 3 | — | 24.38 | 23.7501 | — |
| Polymer 1 | 2.45 | 1.76 | 1.7243 | 1.71 |
| Polymer 2 | 5.50 | — | — | — |
| Polymer 3 | — | 3.72 | 3.6362 | 3.60 |
| Polymer 4 | — | — | — | — |
| Additive 1 | 1.98 | 2.05 | 2.0050 | 1.98 |
| Additive 2 | — | 0.29 | 0.2807 | 0.28 |
| Additive 3 | — | 0.25 | 0.2432 | — |
| Additive 4 | 1.80 | 1.86 | 1.8185 | 1.80 |
| Additive 5 | — | 0.50 | 0.4840 | — |
| Additive 6 | 1.80 | 1.86 | 1.8185 | 1.80 |
| Additive 7 | — | — | 0.5567 | — |
| Additive 8 | — | — | 0.3036 | — |
| Additive 9 | — | — | 0.5907 | — |
| Total | 100 | 100 | 100 | 100 |

TABLE 3

| Component | Example | | |
|---|---|---|---|
| (wt %) | 8 | 9 | 10 |
| Second Metal 1 | 47.72 | 46.45 | 12.80 |
| Second Metal 2 | — | — | 34.63 |
| Third Metal 1 | 15.63 | — | 17.27 |
| Third Metal 2 | — | 40.01 | 12.10 |
| Third Metal 3 | 24.38 | — | 11.31 |
| Polymer 1 | — | — | 1.71 |
| Polymer 2 | — | 7.95 | — |
| Polymer 3 | — | — | 3.60 |
| Polymer 4 | 5.48 | — | — |
| Additive 1 | 2.05 | 1.98 | 1.98 |
| Additive 2 | 0.29 | — | — |
| Additive 3 | 0.25 | — | 1.00 |
| Additive 4 | 1.86 | 1.80 | 1.80 |
| Additive 5 | 0.50 | — | — |
| Additive 6 | 1.86 | 1.80 | 1.80 |
| Total | 100 | 100 | 100 |

Each of the pastes are diluted with 1 wt % butyl carbitol to improve print rheology. The pastes are printed on wafers to form Cu electrodes (busbars or contact pads) via a busbar or contact pad screen from Sefar, a stainless steel screen 325 or 165 mesh, with a 12.7 μm emulsion thickness (PEF2), and a 22° or 45° rotation of the mesh. Printing is performed with an AMI screen printer with a ˜0.68 kg down force, with a 200 μm blank wafer on the stage. Print speed is set to between 3-5 inch/sec in a print-print mode. The wafers are printed and put through a BTU Pyramax N₂ reflow oven.

Durability of the Cu electrodes under damp heat (DH; 85° C., 85% relative humidity) aging conditions is determined. Unencapsulated prints of Cu electrodes on silicon are used to monitor the Cu bulk resistivity (ρ). The quality of the tabbing/Cu contacts is also monitored using contact resistivity (ρ_{c}) utilizing the TLM method. With example 5, after 1000 hours of exposure to DH, no degradation of the Cu contacts is seen relative to comparative/conventional Ag contacts.

A series of 5 inch (12.7 cm) monocrystalline silicon cells (wafers) are prepared for application of additional Ag and Cu pastes. Example 5 above is repeated for testing of additional Cu electrodes. The cells all include standard Ag front grids (fingers and busbars), and a rear layer of Al (first electrode). Cu electrodes (second electrodes) are printed directly on top of the Al first electrode. Comparative examples with openings in the rear layer of Al (first electrode) with Ag/Al busbars printed on the openings to form second electrodes are indicated in the Figures by “Ag”. Example 5 is indicated by “Cu R” or simply “Cu”. All cells are from the same batch (i.e., identically processed up to rear side metallization using either the Ag or the Cu). The cells are tabbed through manual soldering.

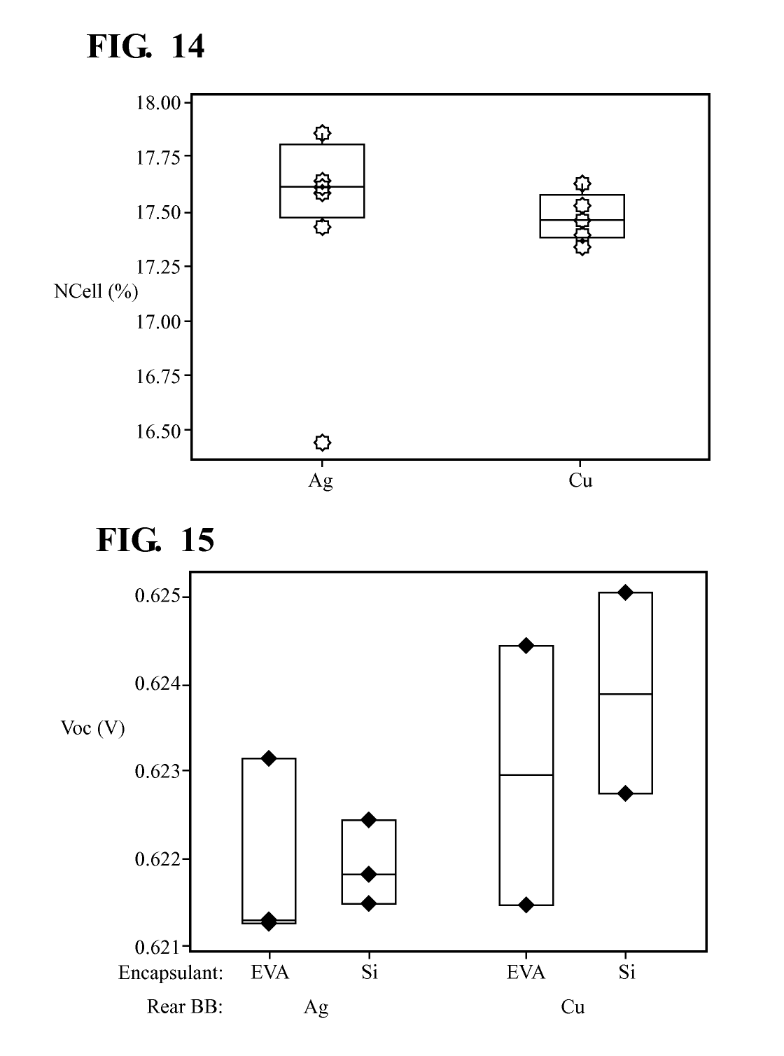

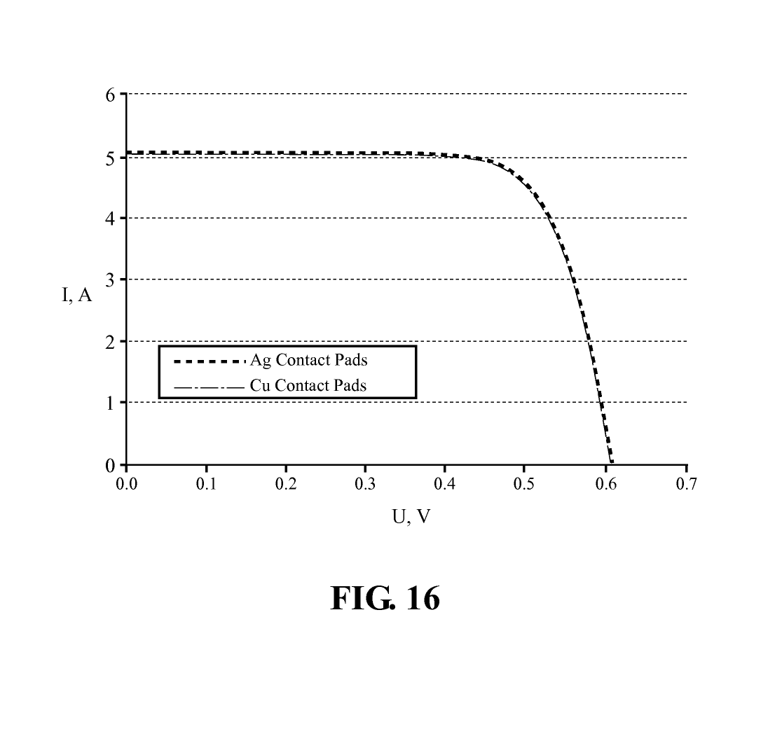

Current-voltage (I-V) measurements using a flash tester (PSS 10 II) are performed. Referring to FIG. 14, I-V data for rear Cu busbar Example 5 compared to Ag busbar examples, as second electrodes, is illustrated. The examples both have front Ag busbars, and are configured as i-PERC cells. Referring to FIG. 15, I-V results for Al BSF cells with Cu busbar Example 5 printed on the rear or Ag controls are illustrated. Cells are encapsulated into mini-modules using either EVA or silicone polymers (denoted as Si). Efficiency is comparable and V_{OC} shows an improvement. FIG. 16 illustrates I-V characteristics of a comparative cell having Ag contacts on Al and an invention cell having Cu contacts, per Example 5, on Al. As shown in FIG. 16, the Cu contact pads do not have a negative impact on cell performance.

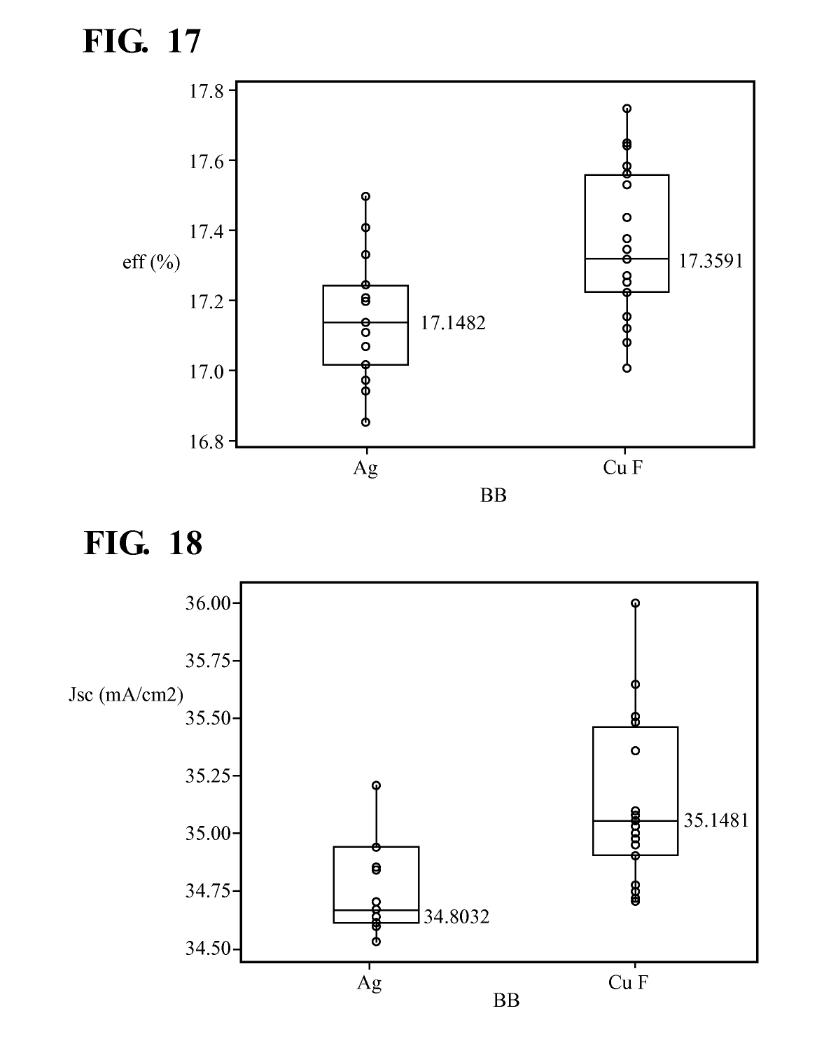

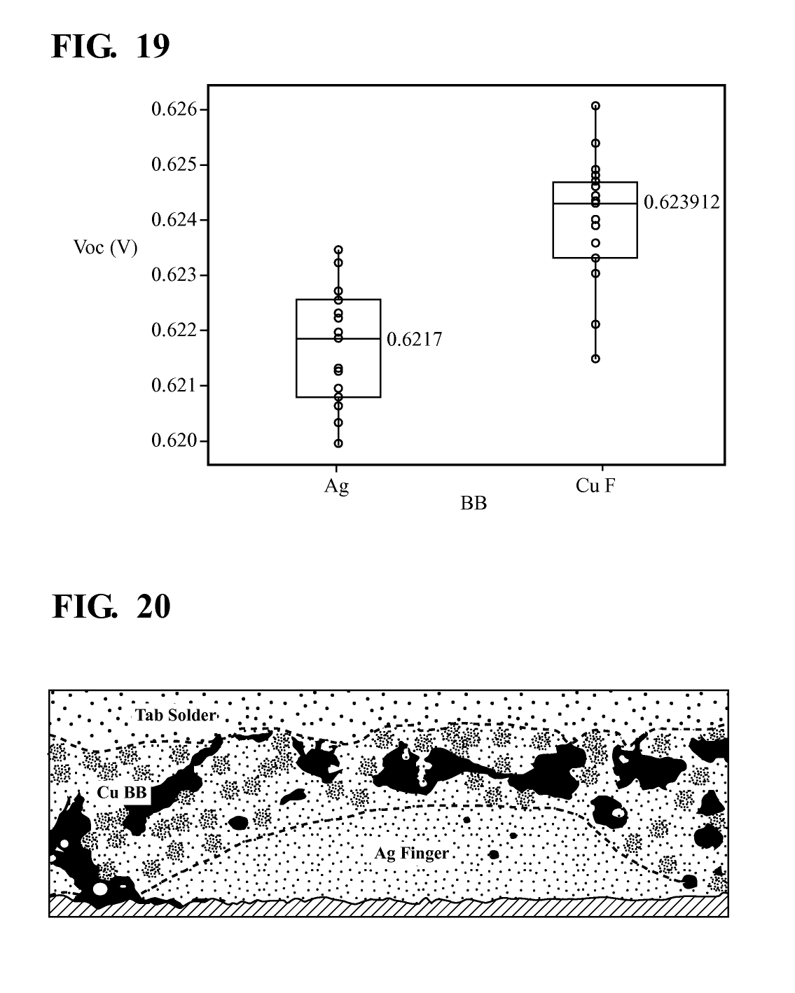

Referring to FIG. 17, a box graph illustrating efficiency percentage of the comparative and invention PV cells is depicted, whereas FIG. 18 illustrates J_{SC}, and FIG. 19 illustrates V_{OC} of the examples. Specifically, IV data for samples is measured. Ag examples are 149-1 through -15, and Cu F examples are 149-A through -S. Mean values are shown. The comparative and invention examples are the same as described above in the previous example Figures. From the data, it is clearly shown that the use of the Cu busbar of the present invention has a distinct improvement in cell performance. This improvement is believed to come from the reduced recombination by reducing the metal/silicon interface area with reduced high temperature fired Ag metallization points.

FIG. 20 is a cross-sectional optical microscopy photograph illustrating a tabbed busbar of the invention. Specifically, a Cu busbar is printed on top of a SiNx passivation layer and on top a Ag finger and later tabbed. Various components of the invention composition are shown in the cross-section. A direct solder bond to the tabbing/busbar and busbar/finger is shown, as well as the adhesive contact between the Cu busbar and the substrate.

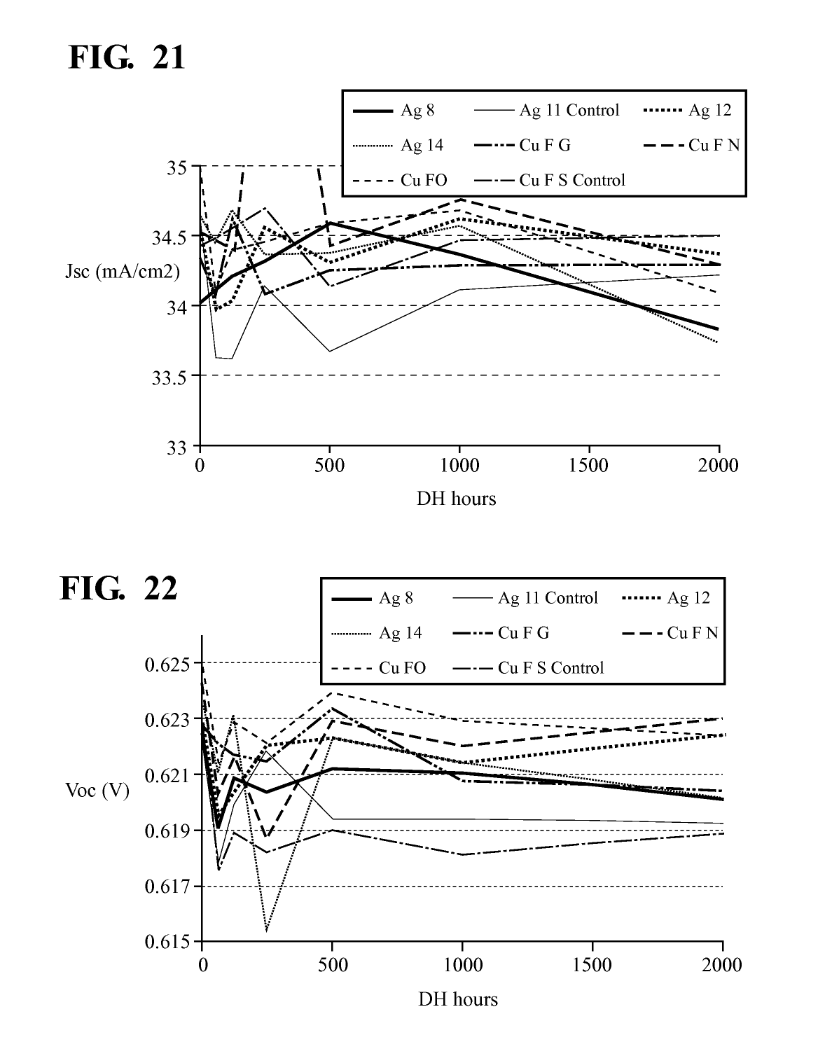

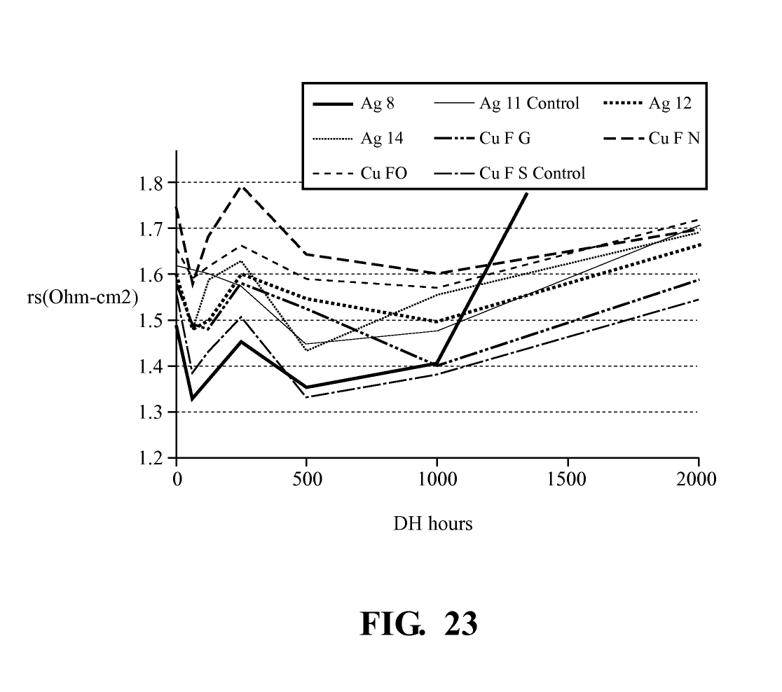

FIG. 21 is a line graph illustrating J_{SC} of comparative and invention PV cell examples after damp heat aging. FIG. 22 is a line graph illustrating V_{OC} of the comparative and invention PV cells after damp heat aging, and FIG. 23 is a line graph illustrating sheet resistivity (rs) of the comparative and invention PV cell examples after damp heat aging. From these graphs it is clear that the Cu paste is not degrading performance under corrosive conditions.

One or more of the values described above may vary by ±5%, ±10%, ±15%, ±20%, ±25%, etc. so long as the variance remains within the scope of the disclosure. Unexpected results may be obtained from each member of a Markush group independent from all other members. Each member may be relied upon individually and or in combination and provides adequate support for specific embodiments within the scope of the appended claims. The subject matter of all combinations of independent and dependent claims, both singly and multiply dependent, is herein expressly contemplated. The disclosure is illustrative including words of description rather than of limitation. Many modifications and variations of the present disclosure are possible in light of the above teachings, and the disclosure may be practiced otherwise than as specifically described herein.

1. A photovoltaic cell comprising:
a base substrate comprising silicon and including a rear region;
a first electrode disposed on said rear region of said base substrate and having an outer surface, with said first electrode in electrical contact with said rear region of said base substrate and comprising a first metal present in said first electrode in a majority amount; and
a second electrode spaced from said rear region of said base substrate such that said rear region of said base substrate is free of physical contact with said second electrode, with said second electrode in electrical contact with said first electrode;
wherein said second electrode comprises;
a polymer,
a second metal present in said second electrode in a majority amount, and
a third metal different from said first metal of said first electrode and said second metal of said second electrode with said third metal having a melting temperature of no greater than about 300° C.; and
wherein said rear region of said base substrate is in electrical communication with said second electrode via said first electrode.

2. The photovoltaic cell as set forth in claim 1,
wherein said second electrode is formed at a temperature of no greater than about 300° C. from a composition enabling said second electrode to be formed at said temperature, with said composition comprising;
said polymer,
said second metal, and
said third metal.

3. A photovoltaic cell comprising:
a base substrate comprising silicon and including a rear region selected from an n-type doped region and/or a p-type doped region;
a first electrode disposed on said rear region of said base substrate and having an outer surface, with said first electrode in electrical contact with said rear region of said base substrate and comprising a first metal comprising aluminum and/or silver present in said first electrode in a majority amount; and
a second electrode spaced from said rear region of said base substrate such that said rear region of said base substrate is free of physical contact with said second electrode, with said second electrode in electrical contact with said first electrode;
wherein said second electrode comprises;
a polymer comprising an epoxy, an acrylic, or a combination thereof,
a second metal comprising copper or silver present in said second electrode in a majority amount, and
a third metal comprising solder with said solder having a melting temperature of no greater than about 300° C.; and
wherein said rear region of said base substrate is in electrical communication with said second electrode via said first electrode.

4. The photovoltaic cell as set forth in claim 1, wherein said rear region is further defined as a rear doped region.

5. The photovoltaic cell as set forth in claim 4, wherein said base substrate further includes an upper doped region opposite said rear doped region.

6. The photovoltaic cell as set forth in claim 1, wherein said rear region of said base substrate is an n-type doped region and/or a p-type doped region.

7. The photovoltaic cell as set forth in claim 1, further comprising a passivation layer disposed on said region(s) of said base substrate with said passivation layer comprising SiO_{X}, ZnS, MgF_{X}, SiN_{X}, SiCN_{X}, AlO_{X}, TiO₂, a transparent conducting oxide (TCO), or combinations thereof.

8. The photovoltaic cell as set forth in claim 1, wherein said first metal of said first electrode comprises aluminum and/or silver, said second metal of said second electrode comprises copper or silver, alternatively copper, and said third metal of said second electrode comprises solder.

9. The photovoltaic cell as set forth in claim 1, wherein said first metal of said first electrode comprises aluminum and/or silver and said second metal of said second electrode comprises copper.

10. The photovoltaic cell as set forth in claim 3, wherein said solder of said second electrode comprises a tin alloy and said polymer of said second electrode comprises an epoxy, an acrylic, or a combination thereof.

11. The photovoltaic cell as set forth in claim 1, wherein said second electrode is formed from a composition comprising;
a copper powder as said second metal,
a solder powder which melts at lower temperature than melting temperature of said copper powder, as said third metal, and
said polymer, or a monomer which is polymerisable to yield said polymer.

12. The photovoltaic cell as set forth in claim 1, wherein said second electrode is:
i) a pad or a busbar;
ii) directly solderable; or
iii) both i) and ii).

13. (canceled)

14. The photovoltaic cell as set forth in claim 1, wherein said first electrode defines a least one hole and said second electrode is disposed over and at least partially within said at least one hole for electrical contact with said base substrate.

15. The photovoltaic cell as set forth in claim 1, further defined as an emitter-wrap through (EWT) photovoltaic cell wherein said base substrate defines a plurality of contact holes and said second electrode is further defined as a plurality of second electrodes with a second electrode disposed in each of said contact holes.

16. The photovoltaic cell as set forth in claim 1, further defined as a metal-wrap through (MWT) photovoltaic cell wherein said base substrate defines a plurality of contact holes and said second electrode is further defined as a plurality of second electrodes with a second electrode disposed in each of said contact holes and in contact with a plurality of fingers disposed opposite said base substrate.

17. A photovoltaic cell module comprising a plurality of said photovoltaic cells as set forth in claim 1, and further comprising at least one ribbon in physical contact with said second electrodes of said photovoltaic cells such that said photovoltaic cells are in electrical communication with each other via said ribbon.

18. A method of forming a photovoltaic cell comprising a base substrate comprising silicon and including a rear region, a first electrode disposed on the rear region of the base substrate and having an outer surface, with the first electrode in electrical contact with the rear region of the base substrate and comprising a first metal present in the first electrode in a majority amount, and a second electrode spaced from the rear region and in electrical contact with the first electrode, said method comprising the steps of:
applying a composition to the outer surface of the first electrode to form a layer such that the rear region of the base substrate is free of physical contact with the layer; and
heating the layer to a temperature of no greater than about 300° C. to form the second electrode;
wherein the composition comprises;
a polymer,
a second metal present in the composition in a majority amount, and
a third metal different from the first metal of the first electrode and the second metal of the composition; and
wherein the rear region of the base substrate is in electrical communication with the second electrode via the first electrode.

19. The method as set forth in claim 18, wherein the first metal of the first electrode comprises aluminum and/or silver, the second metal of the composition comprises copper or silver, alternatively copper, and the third metal of the composition comprises solder.

20. The method as set forth in claim 18, wherein applying the composition is further defined as:
i) printing the composition on the outer surface of the first electrode to define the second electrode; or
ii) electrochemically depositing the composition on the outer surface of the first electrode to define the second electrode.

21. (canceled)

22. The method as set forth in claim 18, wherein the composition comprises;
a copper powder as the second metal,
a solder powder which melts at lower temperature than melting temperature of the copper powder, as the third metal, and
the polymer, or a monomer which is polymerisable to yield the polymer.
